(19) United States
(12) Patent Application Publication
(10) Pub. No.: US 2018/0242460 A1
(43) Pub. Date: Aug. 23, 2018

(54) CONNECTOR MODULE

(71) Applicant: Robert Bosch GmbH, Stuttgart (DE)

(72) Inventors: Eszter Varga, Budapest (HU); Frank Schou, Ditzingen (DE); Jian Zhu, Jiangsu (CN); Peter Gyimesi, Budapest (HU); Timea Sesztak, Budapest (HU); Jesus Omar Murillo Murguia, Budapest (HU)

(21) Appl. No.: 15/882,223

(22) Filed: Jan. 29, 2018

(30) Foreign Application Priority Data
Feb. 20, 2017 (CN) 201710090904.1

(51) Int. Cl. H05K 3/30; H01G 2/06; H01G 9/08; H01G 9/14

(52) U.S. Cl. CPC H05K 3/301; H01G 2/06; H01G 9/08; H01G 9/14; H01R 12/7023; H05K 2201/10325; H05K 2201/1059; H05K 3/308; H05K 2201/10015

(57) ABSTRACT

A connector module for connecting an energy store to a printed circuit board, wherein the connector module is designed in such a way as to receive at least two electrolytic capacitors as energy stores.

### CROSS REFERENCE

The present application claims the benefit under 35 U.S.C. § 119 of China Patent Application No. CN 201710090904.1 filed on Feb. 20, 2017, which is expressly incorporated herein by reference in its entirety.

### FIELD

The present invention relates to a connector module, in particular for connecting an energy store, in particular an electrolytic capacitor, to a printed circuit board.

The connector module is preferably intended to be used in controllers in the automotive sector, in particular in controllers with increased requirements in respect of fail-safety, such as in controllers for tripping personal protection devices for vehicles (airbag controllers) for example.

### BACKGROUND INFORMATION

Controllers with increased requirements in respect of fail-safety, in particular controllers for tripping personal protection devices for vehicles (airbag controllers), typically have their own energy reserve in order to nevertheless be functional as intended for a specific time (autonomous mode) in cases in which the controller is disconnected from the vehicle-side energy supply (vehicle battery).

In this case, the energy store is typically provided in the form of correspondingly dimensioned electrolytic capacitors. The electrolytic capacitors can be connected to the controller in an extremely wide variety of ways. In the event of direct connection by means of the printed circuit board, the electrolytic capacitor is typically soldered onto the printed Circuit board in an upright manner.

As an alternative, the electrolytic capacitor can be connected to the printed circuit board in a horizontal manner. Holders, so-called connector modules, are typically used for this purpose.

German Patent Application No. DE 10 2009 001698 A1 describes a connector module which can be designed such that it establishes a connection between a component, such as an electrolytic capacitor for example, and a printed circuit board while it carries the component at a distance from the printed circuit board. In one embodiment, the module can have a body with fingers and carrier elements which hold and carry the capacitor. The body can have a large number of legs, wherein each leg has elements which are arranged with an intermediate space in relation to one another and which fit into corresponding openings in the printed circuit board. Each leg can have a restraint apparatus and a clamping element which interact in order to fixedly hold the module securely on the printed circuit board. The body can have pins which grasp electrodes of the capacitor and establish a connection to the printed circuit board. In some embodiments, a latching-in cover can have a ring which surrounds the capacitor body and also ensures a secure connection between the electrodes of the capacitor and the pins of the module.

One disadvantage of the connector module from the prior art is that the connector module can receive only one single electrolytic capacitor. The need to provide more than one electrolytic capacitor can arise for a variety of reasons. Firstly, it may be the case that a single electrolytic capacitor cannot provide enough storage for energy. Furthermore, it may be the case that a second electrolytic capacitor has to be provided in order to provide energy in a redundant manner.

### SUMMARY

In accordance with the present invention, a connector module is provided for connecting an energy store to a printed circuit board, wherein the connector module is designed in such a way as to receive at least two electrolytic capacitors as energy stores.

One advantage of the connector module according to the present invention is that firstly the size of the energy store can be set in a correspondingly variable manner by means of the sizes of the respective electrolytic capacitors and in a manner matched to the intended application.

Furthermore, a redundant energy store can be provided owing to at least two electrolytic capacitors being received.

Furthermore, on account of the connector module being designed in such a way as to receive two electrolytic capacitors as energy stores, surface area on a printed circuit board, to which the energy store is intended to be connected by means of the connector module, can be saved since connecting elements for connecting the connector module to the printed circuit board can be saved.

According to one embodiment of the connector module of the present invention, the connector module has only one receiving element for receiving the connections of the at least two electrolytic capacitors. In this embodiment, the connector module is intended to receive electrolytic capacitors of which the connections are arranged only on one side of the capacitor body. The connector module is then designed in such a way that the at least two electrolytic capacitors are arranged in the connector module in such a way that the sides of the electrolytic capacitors face one another by way of the connections of the electrolytic capacitors.

In the present case, a receiving element is intended to be understood to be a component which is suitable for receiving the connections of the electrolytic capacitors and establishing an electrically conductive connection. It is clear that an electrolytic capacitor has both an electrically positive and an electrically negative connection in the form of electrodes. In this case, the receiving element is designed such that it can receive both electrodes such that an electrical connection can be established but no short circuit is produced. Insulation-displacement terminals (IDC) are preferably used as the receiving element.

The advantage of this embodiment is that, in addition to a saving on connecting components for connecting the connector module to the printed circuit board, receiving elements for receiving the connections of the at least two electrolytic capacitors can also be saved since the at least two electrolytic capacitors can share common receiving elements.

In the present case, connecting elements are intended to be understood to be components with which primarily a mechanical connection can be established between the connector module and the printed circuit board. Techniques which do not involve soldering, screwing or insulation-stripping, so-called LSA techniques, are preferably used for this purpose. These techniques have the advantage that a separate soldering step for fastening the energy store can be dispensed with. This simplifies the production of controllers with a separate energy store. A common LSA technique is the use of press-in pins.

The connecting elements can optionally also be provided for establishing an electrical connection between the energy store, that is to say the at least two electrolytic capacitors, and the printed circuit board.

Furthermore, lines on the printed circuit board can advantageously be saved owing to this embodiment since the connection sides of the electrolytic capacitors face one another and therefore more than one electrolytic capacitor can be connected to the printed circuit board by means of the common receiving elements.

According to an alternative embodiment of the connector module according to the present invention, the at least two electrolytic capacitors each have a longitudinal extent, wherein the connector module is designed in such a way that the at least two electrolytic capacitors are arranged in the connector module in such a way that the electrolytic capacitors are arranged parallel to one another with respect to their longitudinal extent.

According to an alternative embodiment of the connector module according to the present invention, the at least two electrolytic capacitors each have a longitudinal extent, wherein the connector module is designed in such a way that the at least two electrolytic capacitors are arranged in the connector module in such a way that the electrolytic capacitors are arranged at an angle which is different from zero, in particular at an angle of from 55° to 65°, in particular at an angle of 60°, in relation to one another with respect to their longitudinal extent.

In this case, the angle used is dictated by the layout of the printed circuit board for which the conductor module is provided, and also by the size of the electrolytic capacitors used. One advantage of this embodiment is that the available enclosed space can be utilized in an optimum manner owing to the arrangement of the electrolytic capacitors which are typically among the largest electrical and/or electronic components of a controller.

The two embodiments of the connector module according to the present invention presented above are advantageously designed in such a way that the at least two electrolytic capacitors are arranged in the connector module in such a way that the respective ends bear against the same side by way of their connections.

This embodiment assumes that the at least two electrolytic capacitors each have their connections only at one end of their longitudinal extent.

One advantage of this embodiment is that receiving elements for receiving the connections of the at least two electrolytic capacitors have to be provided only on one side of the connector module. As a result, the design of the connector module is simpler. In addition, connection of the connector module to the printed circuit board is simplified since connecting points for the connecting elements of the connector module have to be provided at fewer points on the printed circuit board. In addition, lines can be saved on the printed circuit board in this way since the respective connections of the electrolytic capacitors lie close to one another.

According to an improved variant of the above embodiments of the connector module according to the present invention, the connector module has at least one press-in pin for making contact with the printed circuit board, wherein the connector module is designed in such away that, in a state in which the connector module is connected to the printed circuit board, at least one of the at least one press-in pins makes contact with the printed circuit board at an edge region of the printed circuit board.

The advantage of this embodiment is that less space, which is provided for receiving electrical and/or electronic components, has to be used on the printed circuit board in order to connect the connector module to the printed circuit board. As a result, space can be saved on the printed circuit board in this way. This ensures a low weight, a smaller surface area requirement and also a low level of consumption of resources.

It is clear to a person skilled in the art that the saving effect is greater the greater the number of press-in pins provided on the edge region of the printed circuit board. In addition, it is clear to a person skilled in the art that it is not possible to always provide all of the press-in pins on the edge region of the printed circuit board for reasons of contact reliability, robustness and vibration damping.

Below, embodiments of the present invention are explained and illustrated with reference to figures.

### BRIEF DESCRIPTION OF THE DRAWINGS

FIGS. 1a-d show views of a connector module according to a first embodiment in a first type of use.

FIG. 2 shows a perspective view of a connector module according to the first embodiment in the first type of use

FIGS. 3a-c show views of a connector module according to the first embodiment in a second type of use.

FIG. 4 shows a perspective view of a connector module according to the first embodiment in the second type of use.

FIGS. 5a-b show views of a connector module according to a second embodiment.

FIGS. 6a-b show views of a connector module according to a third embodiment.

FIGS. 7a-b show views of a connector module according to a fourth embodiment.

### DETAILED DESCRIPTION OF EXAMPLE EMBODIMENTS

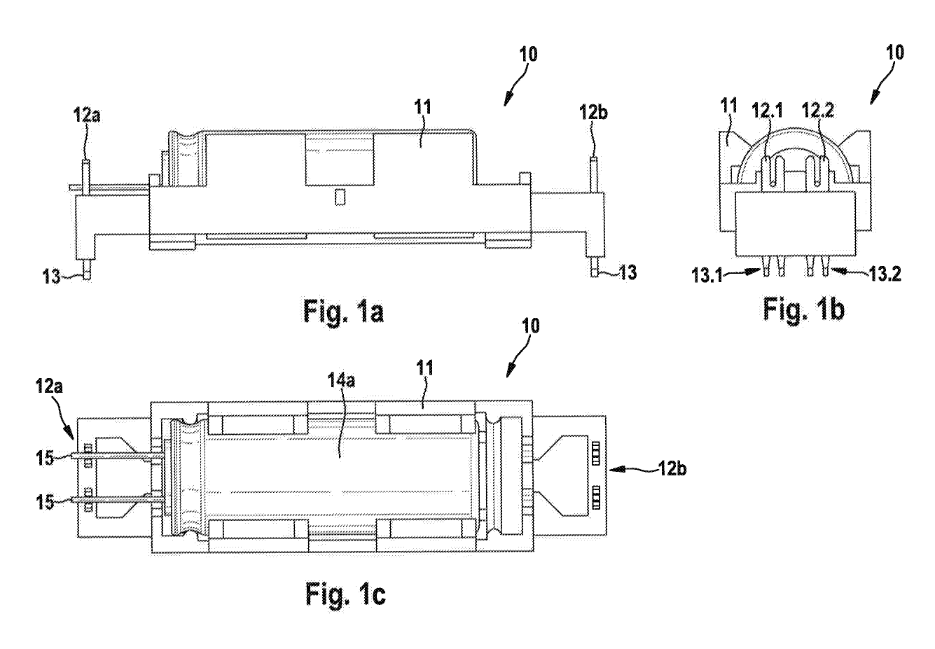

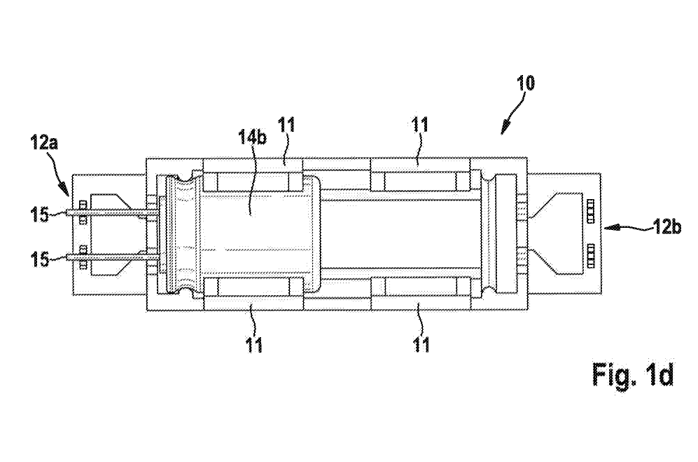

FIG. 1a shows a side view of a connector module 10 according to the present invention in a first type of use. The view shows the side of the longitudinal extent of the connector module 10. In this case, the connector module 10 has a receiving region 11 for receiving and holding an energy store 14a. In the illustrated embodiment, an electrolytic capacitor 14a is used as the energy store 14a. Furthermore, the connector module 10 has receiving elements 12 for connecting electrolytic capacitors 14a. The connections 15 of the electrolytic capacitors 14a are located at the respective ends of the longitudinal extent of the connector module 10. The illustrated receiving elements 12 are insulation-displacement terminals. Furthermore, the connector module 10 has connecting elements 13 for connecting the connector module 10 to a printed circuit board. In this case, the connecting elements 13 are likewise arranged at the respective ends of the longitudinal extent of the connector module 10. The illustrated connecting elements 13 are press-in pins 13. In the illustrated variant, the press-in pins 13 perform two tasks. Firstly, they ensure mechanical connection of the connector module 10 to the printed circuit board. Secondly, the illustrated press-in pins 13 are the extension of the insulation-displacement terminals 12. Therefore, electrical connection of the energy store 14a to the printed circuit board is also established by means of the press-in pins 13.

Yet further connecting elements 13 can be provided for reasons of mechanical or electrical contact reliability, robustness and vibration damping. Said further connecting elements may likewise be press-in pins. Connecting elements 13 for implementing other connection techniques are also feasible.

FIG. 1b likewise shows a side view of the connector module 10 according to the present invention in a first type of use. The view shows the side of the transverse extent of the connector module 10. It can be seen in this view that the connecting elements 13 are pairs of press-in pins 13.1, 13.2.

In detail, this means: the respectively electrically positive or electrically negative connection of the electrolyte capacitor 14a is pressed into the respective insulation-displacement terminals 12.1, 12.2 as the receiving element 12. In extension, the receiving element 12 forms the connecting element 13 as a pair of press-pins 13.1, 13.2. Accordingly, both the insulation-displacement terminal 12.1, which receives the electrically positive connection, and the insulation-displacement terminal 12.2, which receives the electrically negative connection of the electrolytic capacitor 14a, are both mechanically and electrically connected to the printed circuit board by means of a pair of press-in pins 13.1, 13.2.

FIG. 1c shows a plan view of the connector module 10 according to the present invention in a first type of use. This view clearly shows that only one electrolytic capacitor 14a is arranged in the connector module 10 according to the first type of use. Therefore, only one of the receiving elements 12a is used for connecting the electrolytic capacitor 14a to the connector module 10 according to this type of use. The other receiving element 12b remains unused.

FIG. 1d likewise shows a plan view of the connector module 10 according to the present invention in the first type of use. The difference from the design according to FIG. 1c is that, instead of an electrolytic capacitor 14a, which uses all of the available length of the connector module 10, the electrolytic capacitor 14b illustrated here uses only a portion of the available length of the connector module 10.

The flexible use of the connector module 10 is particularly clear from the illustrations of FIGS. 1c and 1d. The correspondingly adapted electrolytic capacitor 14a, 14b can be used depending on the application.

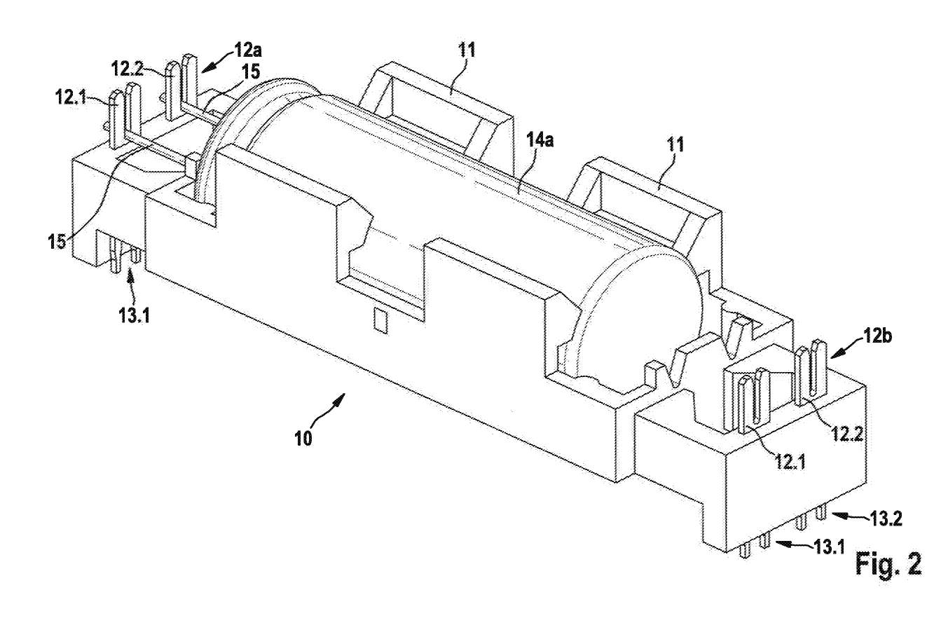

FIG. 2 shows a perspective view of the connector module 10 according to the present invention in the first type of use with an electrolytic capacitor 14a which takes up all of the available length of the connector module. The unused receiving element 12b can be clearly seen in this view.

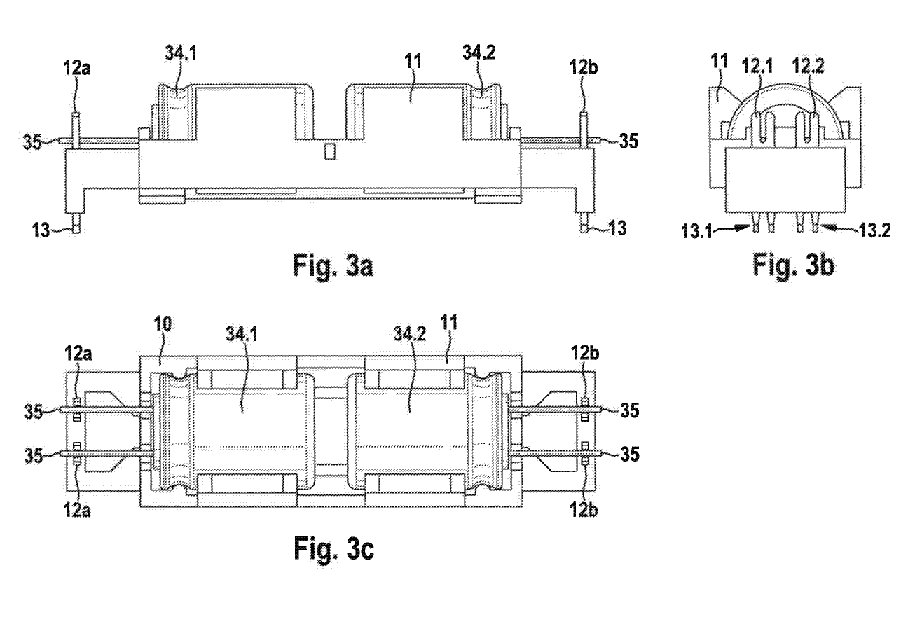

FIG. 3a shows a side view of the connector module 10 according to the present invention in a second type of use. The view shows the side of the longitudinal extent of the connector module 10. Since the illustrated connector module 10 is the same embodiment of the connector module 10 as in FIGS. 1a-d and 2, the following section concentrates on the second type of use.

According to the second type of use, two electrolytic capacitors 34.1, 34.2 are arranged in the connector module 10. The sides of the electrolytic capacitors 34.1, 34.2, which have the Connections 35.1, 35.2, are directed towards the outside here. In this case, two electrolytic capacitors 34.1, 34.2 can be connected to the printed circuit board by a single connector module 10. As a result, a redundant energy store can be provided.

FIGS. 3b and 3c respectively show a side view and a plan view of the connector module 10 according to the present invention in the second type of use.

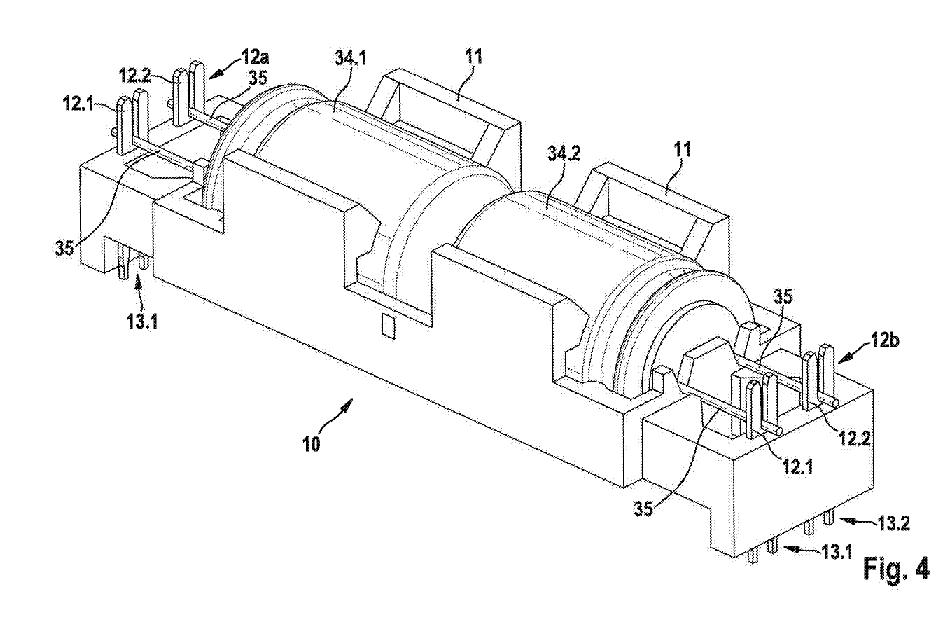

FIG. 4 shows a perspective view of the connector module 10 according to the present invention in the second type of use with two electrolytic capacitors 34.1, 34.2 which are arranged in the connector module 10 such that the sides of the electrolytic capacitors 34.1, 34.2, which have the connections 35, 35, face towards the outside. According to the second type of use, the receiving elements 12a, 12b are used on both sides of the connector module 10 in order to both electrically connect the respective electrolytic capacitor 34.1, 34.2 to the printed circuit board by means of the connector module 10 and also mechanically connect the connector module 10 to the printed circuit board.

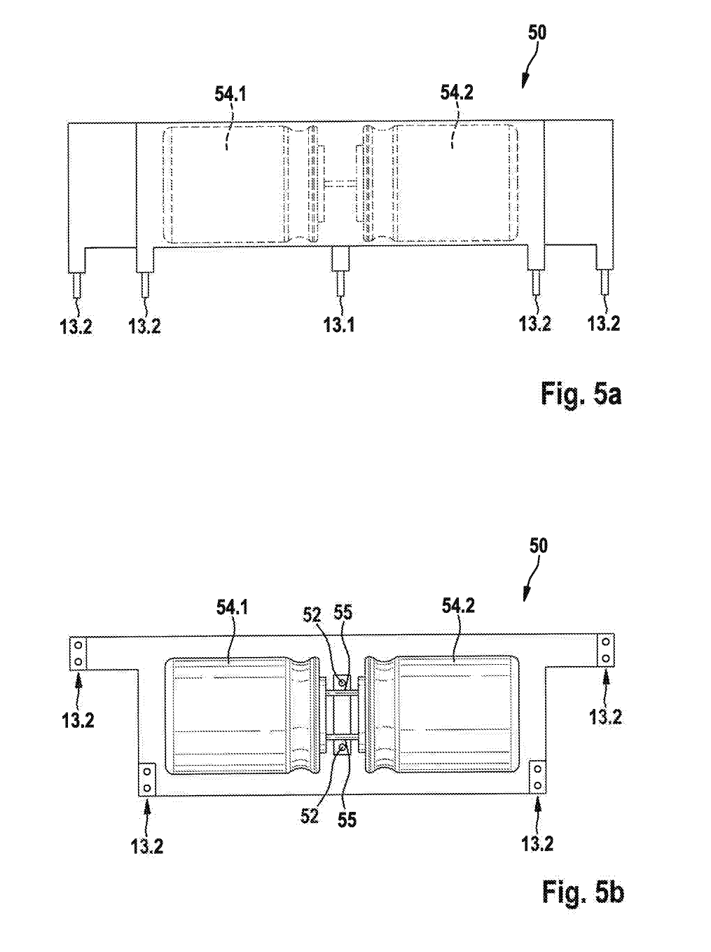

FIG. 5a shows a side view of the connector module 50 according to a second embodiment. According to this embodiment, the connector module 50 has only one receiving element 52 for electrolytic capacitors 54.1, 54.2. In contrast to the first embodiment, the receiving element 52 is not arranged at an end of the longitudinal extent of the connector module 50. Rather, the receiving element is arranged within the connector module 50. The connector module 50 according to the second embodiment is designed in such a way that the electrolytic capacitors 54.1, 54.2 are arranged in the connector module 50 in such a way that the sides of the electrolytic capacitors 54.1, 54.2 which have the connections 55, face one another. That is to say, the arranged electrolytic capacitors 54.1, 54.2 share a common receiving element 52.

The receiving element 52 is preferably likewise designed as an insulation-displacement terminal. In this embodiment too, electrical contact is made with the printed circuit board by means of an extension of the receiving element 52, which extension forms press-in pins 13.1.

In addition to the press-in pins 13.1 from the extension of the receiving element 52, this embodiment has press-in pins 13.2 which are designed only to mechanically connect the connector module 50 to the printed circuit board. These press-in pins 13.2 are arranged on the outer edge of the connector module 50.

FIG. 5b shows a plan view of the connector module 50 according to the second embodiment. The receiving element 52 which is jointly used by the electrolytic capacitors 54.1, 54.2 is clearly illustrated in this view. Furthermore, it can clearly be seen that the expansion of the connector module 50 is not oriented primarily to the expansion of the electrolytic capacitors 54.1, 54.2 which are to be received. Therefore, FIG. 5b clearly shows that the connector module 50 has a region of greater expansion, at the ends of which region a pair of press-in pins 13.2 are arranged in each case. This expansion of the connector module 50 is caused by the layout of the printed circuit board for which the connector module 50 is provided. Therefore, the expansion, in particular of the region with a relatively large expansion, is selected in such a way, since the press-in pins 13.2 can be arranged at an edge region of the printed circuit board as connecting elements in this way, in order to save valuable space on the printed circuit board or to provide for electrical or electronic elements in this way.

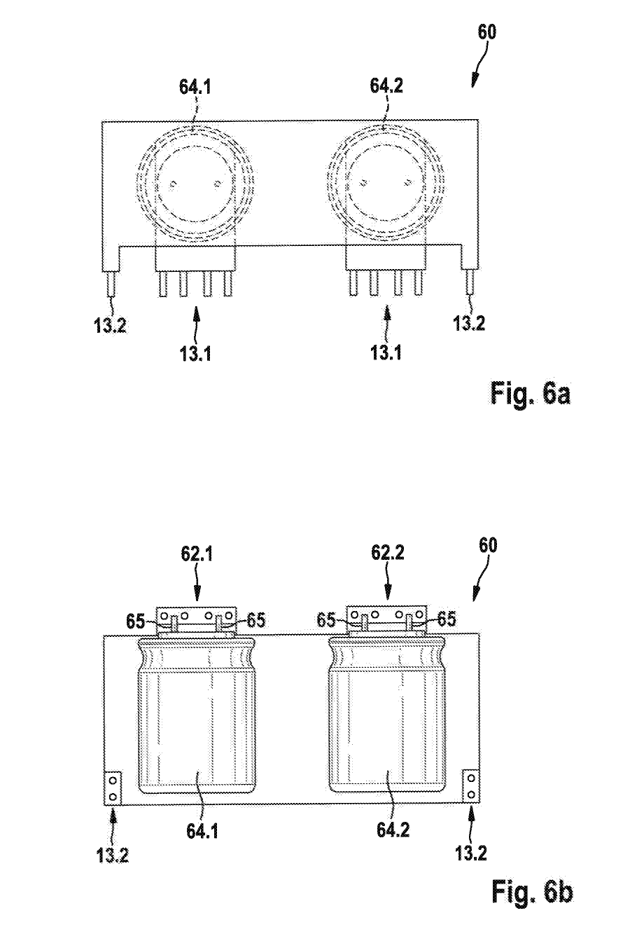

FIG. 6a shows a side view of the connector module 60 according to a third embodiment. According to this embodiment, two electrolytic capacitors 64.1, 64.2 are arranged in the connector module 60 such that the electrolytic capacitors 64.1, 64.2 are arranged parallel to one another with respect to their longitudinal extent.

FIG. 6b shows a plan view of the connector module 60 according to the third embodiment. It can clearly be seen in this view that the electrolytic capacitors 64.1, 64.2 are arranged in the connector module such that the sides of the electrolytic capacitors 64.1, 64.2, which have the connections 65, face in the same direction. In contrast to the preceding embodiment, this embodiment has a separate receiving element 62.1, 62.2 for each electrolytic capacitor 64.1, 64.2. Since, according to the illustrated embodiment, the side of the electrolytic capacitors 64.1, 64.2, which have the connections, face in the same direction, the receiving elements 62.1, 62.2 are accordingly provided on the same side of the connector module 60.

As in the embodiments presented above, the receiving elements 62.1, 62.2 are preferably designed as insulation-displacement terminals. Electrical contact is likewise made with the printed circuit board by means of an extension of the receiving element 61.1, 62.2, which forms press-in pins 13.1, in this embodiment.

In addition to the press-in pins 13.1 from the extension of the receiving element 62.1, 62.2 this embodiment also further has press-in pins 13.2 which are designed merely to mechanically connect the connector module 60 to the printed circuit board.

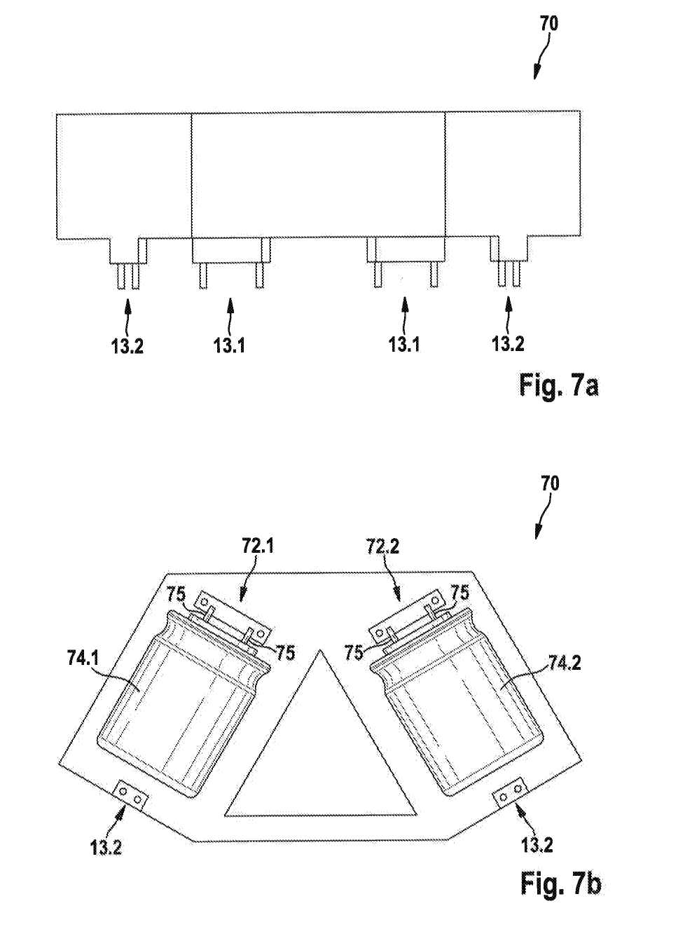

FIG. 7a shows a side view of the connector module 70 according to a fourth embodiment. According to this embodiment, the connecting elements 13.1,13.2 are likewise implemented as pairs of press-in pins. In contrast to the embodiments presented above, the pairs of press-in pins 13.1,13.2 are not oriented parallel to one another. This is due to reasons of design in then exemplary embodiment, but is not compulsory.

FIG. 7b shows a plan view of the connector module 70 according to the fourth embodiment. According to this embodiment, two electrolytic capacitors 74.1, 74.2 are arranged in the connector module such that the electrolytic capacitors 74.1, 74.2 are arranged at an angle which is different from zero in respect of their longitudinal extent. In the illustrated variant, the angle is 60°.

In this case, the angle used is dictated by the layout of the printed circuit board for which the connector module 70 is provided and also by the size of the electrolytic capacitors 74.1, 74.2 used. The objective of this embodiment is firstly of the receiving elements 72.1, 72.2 for the connections 75 of the electrolytic capacitors 74.1, 74.2 lying as close to one another as possible in order to have to use as little line as possible on the printed circuit board. Secondly, the connector module 70 is intended to be designed in such a way that the connecting elements 13.1, 13.2 for making mechanical contact make contact with the printed circuit board at an edge region in order to provide space on the printed circuit board for other electrical or electronic components in this way.

What is claimed is:

1. A connector module for connecting an energy store to a printed circuit board, the connector module being designed in such a way as to receive at least two electrolytic capacitors as energy stores.

2. The connector module according to claim 1, wherein the at least two electrolytic capacitors have connections on only one side, wherein the connector module has only one receiving element for receiving the connections of the at least two electrolytic capacitors, and the connector module is designed in such a way that the at least two electrolytic capacitors are arranged in the connector module in such a way that the sides of the electrolytic capacitors face one another by way of their connections.

3. The connector module according to claim 1, wherein the at least two electrolytic capacitors each has a longitudinal extent, wherein the connector module is designed in such a way that the at least two electrolytic capacitors are arranged in the connector module in such a way that the electrolytic capacitors are arranged parallel to one another with respect to their longitudinal extent.

4. The connector module according to claim 1, wherein the at least two electrolytic capacitors each has a longitudinal extent, wherein the connector module is designed in such a way that the at least two electrolytic capacitors are arranged in the connector module in such a way that the electrolytic capacitors are arranged at an angle which is different from zero, in relation to one another with respect to their longitudinal extent.

5. The connector module according to claim 4, wherein the angle is from 55° to 65°.

6. The connector module according to claim 5, wherein the angle is 60°.

7. The connector module according to claim 3, wherein the at least two electrolytic capacitors have their connections in each case only at one end of their longitudinal extent, wherein the connector module is designed in such a way that the at least two electrolytic capacitors are arranged in the connector module in such a way that the respective ends bear against the same side by way of their connections.

8. The connector module according to claim 1, wherein the connector module has at least one press-in pin for making contact with the printed circuit board, wherein the connector module is designed in such a way that, in a state in which it is connected to the printed circuit board, at least one of the at least one press-in pins makes contact with the printed circuit board at an edge region of the printed circuit board.
